(19) United States
(12) Patent Application Publication
(10) Pub. No.: US 2026/0068178 A1
(43) Pub. Date: Mar. 5, 2026

(54) SEMICONDUCTOR DEVICES AND FABRICATING METHODS THEREOF

(71) Applicant: Yangtze Memory Technologies Holding Co., Ltd., Wuhan (CN)

(72) Inventors: Liang Xiao, Wuhan (CN); Min Wen, Wuhan (CN); Yi Zhao, Wuhan (CN); Wenbin Zhou, Wuhan (CN); Zongliang Huo, Wuhan (CN)

(73) Assignee: Yangtze Memory Technologies Holding Co., Ltd., Wuhan (CN)

(21) Appl. No.: 18/935,284

(22) Filed: Nov. 1, 2024

Related U.S. Application Data
(63) Continuation of application No. PCT/CN2024/115847, filed on Aug. 30, 2024.

(51) Int. Cl. H10B 80/00; H01L 23/00; H01L 25/00; H01L 25/065; H01L 25/18

(52) U.S. Cl. CPC H10B 80/00

(57) ABSTRACT

A disclosed semiconductor device includes vertically stacked first and second semiconductor stacks. The first semiconductor stack includes a first memory array layer comprising first arrays of memory cells, a first peripheral circuit layer including first transistors formed on a first semiconductor layer, and a first interconnect structure vertically extending through the first semiconductor stack, located between adjacent first arrays of memory cells, and penetrating through the first semiconductor layer. The second semiconductor stack includes a second memory array layer including second arrays of memory cells, a second peripheral circuit layer comprising second transistors formed on a second semiconductor layer, and a second interconnect structure vertically extending through the second semiconductor stack, located between adjacent arrays of memory cells, and penetrating through the first semiconductor layer. The first interconnect structure is in contact with the second interconnect structure, and the first semiconductor layer faces the second semiconductor layer.

### CROSS-REFERENCE TO RELATED APPLICATIONS

This application is a continuation of International Application No. PCT/CN2024/115847, filed on Aug. 30, 2024, which is hereby incorporated by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

Some aspects of the present disclosure provide a semiconductor structure, comprising: a first semiconductor stack, comprising: a first memory array layer comprising first arrays of memory cells, a first peripheral circuit layer on the first memory array layer, and comprising first transistors formed on a first semiconductor layer, a first bonding layer on the first semiconductor layer, and a first interconnect structure vertically extending through the first semiconductor stack, located between adjacent first arrays of memory cells, and extending through the first semiconductor layer and the first bonding layer; and a second semiconductor stack, comprising: a second memory array layer comprising arrays of memory cells, a second peripheral circuit layer on the second memory array layer, and comprising second transistors formed on a second semiconductor layer, a second bonding layer on the second semiconductor layer, and a second interconnect structure vertically extending through the second semiconductor stack, located between adjacent arrays of memory cells, and extending through the first semiconductor layer and the second bonding layer, wherein the first bonding layer is bonded with the second bonding layer, the first interconnect structure is in contact with the second interconnect structure, the first semiconductor layer is located between the first bonding layer and the first peripheral circuit layer, and the second semiconductor layer is located between the second bonding layer and the second peripheral circuit layer.

In some implementations, each of first arrays and second arrays of memory cells comprises: a transistor layer comprising an array of vertical transistors, each vertical transistor comprising a channel structure extending vertically; and a storage layer vertically stacked on the transistor layer and comprising an array of capacitors each coupled with a corresponding one of the array of vertical transistors.

In some implementations, the first semiconductor stack and the second semiconductor stack are hybrid bonded with each other; and a first conductive pad of the first interconnect structure is in contact with a second conductive pad of the second interconnect structure.

In some implementations, the first bonding layer comprises a first carbon nitride layer where the first conductive pad is embedded; and the second bonding layer comprises a second carbon nitride layer where the second conductive pad is embedded.

In some implementations, the first bonding layer comprises a first silicon oxide layer where the first conductive pad is embedded; and the second bonding layer comprises a second silicon oxide layer where the second conductive pad is embedded.

In some implementations, a thickness of the first semiconductor stack or the second semiconductor stack is less than 12 μm.

In some implementations, the first memory array layer is bonded with the first peripheral circuit layer; and the second memory array layer is bonded with the second peripheral circuit layer.

In some implementations, the first semiconductor stack further comprises a first bridge contact structure laterally extending between the first semiconductor layer and the second semiconductor layer, and vertically extending through the first semiconductor layer twice to interconnect two of the first transistors; and the second semiconductor stack further comprises a second bridge contact structure laterally extending between the first semiconductor layer and the second semiconductor layer, and vertically extending through the second semiconductor layer twice to interconnect two of the second transistors.

In some implementations, the array of capacitors comprises: a plurality of first electrodes coupled with the array of vertical transistors; and a plurality of second electrodes coupled with a common conductive layer.

In some implementations, the common conductive layer comprises: a main lateral plate in contact with the plurality of second electrodes; a vertical plate in contact with an edge of the main lateral plate; and a lateral landing portion in contact with the vertical plate, and in contact with a capacitor interconnection structure, which is coupled with the first transistors or second transistors.

Another aspect of the present disclosure provides a semiconductor structure, comprising: a first semiconductor stack, comprising: a first memory array layer comprising: first arrays of memory cells, and a first through array interconnect structure located between the first arrays of memory cells; a first peripheral circuit layer bonded with the first memory array layer, the first peripheral circuit layer comprising: first transistors formed on a first semiconductor layer, and a first through circuit interconnect structure extending through the first semiconductor layer and in contact with the first through array interconnect structure; and a second semiconductor stack, comprising: a second memory array layer comprising: second arrays of memory cells, and a second through array interconnect structure located between the second arrays of memory cells; a second peripheral circuit layer bonded with the second memory array layer, the second peripheral circuit layer comprising: second transistors formed on a second semiconductor layer, and a second through circuit interconnect structure extending through the second semiconductor layer and in contact with the second through array interconnect structure, wherein the first semiconductor stack is bonded with the second semiconductor stack, such that the first through circuit interconnect structure is in contact with the second through circuit interconnect structure.

In some implementations, each of first arrays and second arrays of memory cells comprises: a transistor layer comprising an array of vertical transistors, each vertical transistor comprising a channel structure extending vertically; and a storage layer vertically stacked on the transistor layer and comprising an array of capacitors each coupled with a corresponding one of the array of vertical transistors.

In some implementations, the first semiconductor stack and the second semiconductor are hybrid bonded with each other; and a first conductive pad of the first through circuit interconnect structure is in contact with a second conductive pad of the second through circuit interconnect structure.

In some implementations, the first conductive pad and the second conductive pad are embedded in a bonding layer including carbon nitride.

In some implementations, the first conductive pad and the second conductive pad are embedded in a bonding layer including silicon oxide.

In some implementations, a thickness of the first semiconductor stack or the second semiconductor stack is less than 12 μm.

In some implementations, the first semiconductor layer and the second semiconductor layer are located between the first memory array layer and the second memory array layer.

In some implementations, the first semiconductor stack further comprises a first bridge contact structure laterally extending between the first semiconductor layer and the second semiconductor layer, and vertically extending through the first semiconductor layer twice to interconnect two of the first transistors; and the second semiconductor stack further comprises a second bridge contact structure laterally extending between the first semiconductor layer and the second semiconductor layer, and vertically extending through the second semiconductor layer twice to interconnect two of the second transistors.

In some implementations, the array of capacitors comprises: a plurality of first electrodes coupled with the array of vertical transistors; and a plurality of second electrodes coupled with a common conductive layer.

In some implementations, the common conductive layer comprises: a main lateral plate in contact with the plurality of second electrodes; a vertical plate in contact with an edge of the main lateral plate; and a lateral landing portion in contact with the vertical plate, and in contact with a capacitor interconnection structure, which is coupled with the first transistors or second transistors.

Another aspect of the present disclosure provides a method of forming a semiconductor structure, comprising: forming a first wafer, comprising: forming a first memory array layer comprising first arrays of memory cells, forming a first peripheral circuit layer on the first memory array layer, and comprising first transistors formed on a first semiconductor layer, and forming a first interconnect structure vertically extending through the first wafer, located between adjacent first arrays of memory cells, and extending through the first semiconductor layer; and forming a second wafer, comprising: forming a second memory array layer comprising arrays of memory cells, forming a second peripheral circuit layer on the second memory array layer, and comprising second transistors formed on a second semiconductor layer, and forming a second interconnect structure vertically extending through the second wafer, located between adjacent arrays of memory cells, and extending through the first semiconductor layer; and bonding the first wafer and the second wafer to form a bonded structure, such that the first interconnect structure is in contact with the second interconnect structure, and the first semiconductor layer is facing the second semiconductor layer.

In some implementations, the method further comprises: after bonding, cutting the bonded structure into a plurality of semiconductor structures.

In some implementations, forming the first memory array layer or the second memory array layer comprises: forming a transistor layer comprising an array of vertical transistors, each vertical transistor comprising a channel structure extending vertically; and forming a storage layer vertically stacked on the transistor layer and comprising an array of capacitors each coupled with a corresponding one of the array of vertical transistors.

In some implementations, bonding the first wafer and the second semiconductor comprises: bonding a first conductive pad of the first interconnect structure to a second conductive pad of the second interconnect structure.

In some implementations, bonding the first wafer and the second semiconductor further comprises: bonding a first bonding layer including a dielectric layer and the first conductive pad to a second bonding layer including carbon nitride and the second conductive pad.

In some implementations, forming the first wafer or the second wafer further comprises: thinning the first semiconductor layer or the second semiconductor layer, such that a thickness of the first wafer or the second wafer is less than 12 μm.

In some implementations, forming the first wafer further comprises bonding the first memory array layer and the first peripheral circuit layer; and forming the second wafer further comprises bonding the second memory array layer and the second peripheral circuit layer.

In some implementations, forming the first wafer further comprises forming a first bridge contact structure laterally extending between the first semiconductor layer and the second semiconductor layer, and vertically extending through the first semiconductor layer twice to interconnect two of the first transistors; and forming the second wafer further comprises forming a second bridge contact structure laterally extending between the first semiconductor layer and the second semiconductor layer, and vertically extending through the second semiconductor layer twice to interconnect two of the second transistors.

In some implementations, forming the storage layer comprises: forming a plurality of first electrodes coupled with the array of vertical transistors; forming a plurality of second electrodes isolated with the plurality of first electrodes by a dielectric layer; and forming a common conductive layer coupled with the plurality of second electrodes.

In some implementations, forming the common conductive layer comprises: forming a main lateral plate in contact with the plurality of second electrodes; forming a vertical plate in contact with an edge of the main lateral plate; and forming a lateral landing portion in contact with the vertical plate, and in contact with a capacitor interconnection structure.

Another aspect of the present disclosure provides a method of forming a semiconductor structure, comprising: forming at least two DRAM wafers, wherein forming each DRAM wafer comprises: forming a memory array layer on a first semiconductor layer, forming a peripheral circuit layer on a second semiconductor layer, thinning the second semiconductor layer, and forming first interconnection structures extending through the second semiconductor layer; bonding a first DRAM wafer to a second DRAM wafer, such that the first interconnection structures of the first DRAM wafer are in contact with the first interconnection structures of the second DRAM wafer.

In some implementations, the method further comprises: bonding a third DRAM wafer to a fourth DRAM wafer, such that the first interconnection structures of the third DRAM wafer are in contact with the first interconnection structures of the fourth DRAM wafer; thinning the first semiconductor layers of the second DRAM wafer and the third DRAM wafer; forming second interconnection structures extending through the first semiconductor layer of the second DRAM wafer and in contact with the first interconnection structures of the second DRAM wafer, or extending through the first semiconductor layer of the third DRAM wafer and in contact with the first interconnection structures of the third DRAM wafer; and bonding the second DRAM wafer to the third DRAM wafer, such that the second interconnection structures of the second DRAM wafer are in contact with the first interconnection structures of the fourth DRAM wafer.

In some implementations, the method further comprises: after bonding the second DRAM wafer to the third DRAM wafer, cutting the bonded structure into a plurality of semiconductor structures.

In some implementations, forming the memory array layer comprises: forming a transistor layer comprising an array of vertical transistors, each vertical transistor comprising a channel structure extending vertically; and forming a storage layer vertically stacked on the transistor layer and comprising an array of capacitors each coupled with a corresponding one of the array of vertical transistors.

In some implementations, forming each DRAM wafer comprises forming a first bonding layer including first conductive pads in a first dielectric layer; and bonding the first DRAM wafer to the second DRAM wafer comprises hybrid bonding the first bonding layer of the first DRAM wafer to the first bonding layer of the second DRAM wafer, such that the first conductive pads in the first bonding layer of the first DRAM wafer are in contact with the first conductive pads in the first bonding layer of the second DRAM wafer.

In some implementations, the method further comprises: after thinning the first semiconductor layers of the second DRAM wafer and the third DRAM wafer, forming second bonding layers on the first semiconductor layers of the second DRAM wafer and the third DRAM wafer, respectively, wherein each second bonding layer comprises second conductive pads in a second dielectric layer; and bonding the second DRAM wafer to the third DRAM wafer comprises hybrid bonding the second bonding layer of the second DRAM wafer to the second bonding layer of the third DRAM wafer, such that the second conductive pads in the second bonding layer of the second DRAM wafer are in contact with the second conductive pads in the second bonding layer of the third DRAM wafer.

In some implementations, forming each DRAM wafer further comprises: bonding the memory array layer and the peripheral circuit layer, such that the memory array layer and the peripheral circuit layer are located between the first semiconductor layer and the second semiconductor layer.

In some implementations, forming each DRAM wafer further comprises: after thinning the second semiconductor layer, forming a bridge contact structure vertically extending through the second semiconductor layer twice to interconnect two of transistors of the peripheral circuit layer.

In some implementations, forming the storage layer comprises: forming a plurality of first electrodes coupled with the array of vertical transistors; forming a plurality of second electrodes isolated with the plurality of first electrodes by a dielectric layer; and forming a common conductive layer coupled with the plurality of second electrodes.

In some implementations, forming the common conductive layer comprises: forming a main lateral plate in contact with the plurality of second electrodes; forming a vertical plate in contact with an edge of the main lateral plate; and forming a lateral landing portion in contact with the vertical plate, and in contact with a capacitor interconnection structure.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a semiconductor device including an array of memory cells according to some implementations of the present disclosure.

FIG. 2A illustrates a schematic block diagram of a cross-section of a first semiconductor device, according to some implementations of the present disclosure.

FIG. 2B illustrates a schematic block diagram of a cross-section of a second semiconductor device, according to some implementations of the present disclosure.

FIG. 2C illustrates a block diagram view of a cross-section of a third semiconductor device, according to some implementations of the present disclosure.

FIG. 3A illustrates a schematic cross-sectional view of a first semiconductor device, according to some implementations of the present disclosure.

FIG. 3B illustrates a schematic cross-sectional view of a second semiconductor device, according to some implementations of the present disclosure.

FIG. 3C illustrates a schematic cross-sectional view of a third semiconductor device, according to some implementations of the present disclosure.

FIG. 4 illustrates a schematic enlarged cross-sectional view of a portion of a semiconductor device, according to some implementations of the present disclosure.

FIG. 5 illustrates a schematic side view of a cross-section of a semiconductor device, according to some implementations of the present disclosure.

FIG. 6 illustrates a flowchart of a fabricating method for forming a semiconductor device, according to some implementations of the present disclosure.

FIGS. 7A-7H each illustrates schematic views of the semiconductor device at a certain fabricating stage of the method shown in FIG. 6, according to various implementations of the present disclosure.

FIG. 8 illustrates a flowchart of a fabricating method for forming a semiconductor device, according to some implementations of the present disclosure.

FIGS. 9A and 9B each illustrates schematic views of the semiconductor device at a certain fabricating stage of the method shown in FIG. 8, according to various implementations of the present disclosure.

FIG. 10 illustrates a flowchart of a fabricating method for forming a semiconductor device, according to some implementations of the present disclosure.

FIGS. 11A and 11B each illustrates schematic views of the semiconductor device at a certain fabricating stage of the method shown in FIG. 8, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some semiconductor devices, such as dynamic radon access memory (DRAM). In a one-transistor-one-capacitor (1T1C) DRAM structure or in a one-transistor-N-capacitor (1TNC) DRAM structure, the data is stored in the capacitors. Traditional DRAM devices adopt a 6F2 architecture, with logic circuits located laterally adjacent to the memory array, resulting in low density and challenges in miniaturization. On the other hand, vertical channel DRAM devices employ a 4F2 architecture, with logic circuits overlapping with the memory array in the vertical direction, thereby saving space and improving density. However, shrinking the size of storage units still presents difficulties, along with high manufacturing costs.

Further, High Bandwidth Memory (HBM) chips are crucial for AI computing power, but traditional HBM implementations face significant challenges due to the use of Through-Silicon Via (TSV) combined with u-bump technology for stacking DRAM dies. There are common but difficult challenges in the industry related to Die-to-Die packaging. The fabricating process involves stacking dies, each being 50-70 μm thick. However, the total package thickness limits the number of layers that can be stacked, making it difficult to exceed 16 layers. Additionally, the size of the U-bump imposes limitations, and the TSVs occupy a considerable amount of die area, leading to higher costs. In addition, mechanical strength requirements prevent the reduction of die thickness, and further reducing the U-bump pitch introduces reliability risks. These constraints pose a significant challenge for scaling HBM technology to meet the increasing demand for higher bandwidth in AI applications.

To address one or more of the aforementioned issues, the present disclosure introduces a multi-deck stacked DRAM architecture with logic circuits positioned stacked with the memory array in the vertical direction. The corresponding fabricating processes of the multi-deck stacked DRAM architecture. Utilizing wafer-to-wafer hybrid bonding for DRAM stacking allows for a significant reduction in die thickness, down to approximately 10 μm, by retaining only the functional memory structures without needing to consider mechanical strength. This fabricating method enables the creation of a 2-DRAM die stack, which can then be stacked in a 2+2 configuration to form a 4-layer DRAM die stack, and so on, ultimately leading to a multi-layer stacked HBM structure.

By utilizing the new multi-deck stacked DRAM architecture and the corresponding new fabrication method, the disclosed semiconductor devices can achieve high memory density with a further reduced size. This approach to HBM development through wafer-to-wafer hybrid bonding offers advantages such as reduced total thickness and higher interconnect density at the same number of stacked layers. Compared to die-to-die hybrid bonding, wafer-to-wafer hybrid bonding offers significant advantages in terms of thickness reduction, interconnect density, and cost efficiency. For example, the total thickness of the HBM stack can be reduced by more than 80%, while the interconnect density increases by over 100 times. This makes wafer-to-wafer hybrid bonding not only more compact but also more capable of handling the high interconnect requirements of advanced HBM designs, all while lowering the overall process costs. It is also noted that, as the wafer stacking process is repeated multiple times, die yield decreases rapidly, especially at higher stacking levels. Consequently, the disclosed method places stringent demands on DRAM die yield, making it crucial to maintain high-quality dies throughout the process to achieve a reliable and efficient multi-layer HBM structure.

Consistent with the scope of the present disclosure, according to some implementations of the present disclosure, the disclosed semiconductor devices include vertical transistors and vertical capacitors. Each vertical transistor includes a semiconductor layer extending in a vertical direction and a gate structure laterally beside the semiconductor layer. In some implementations, the word lines and bit lines connected to the vertical transistors are arranged along a first lateral direction and a second lateral direction, respectively. Each vertical capacitor includes vertically extended first electrode, second electrode, and capacitor dielectric between the first and second electrodes. By employing such an arrangement, memory area efficiency can be increased. Furthermore, the memory cell array and the peripheral circuits can be formed separately on different wafers, such that the fabricating processes of the memory cell array and the peripheral circuits do not affect each other, thereby further increasing the memory area efficiency.

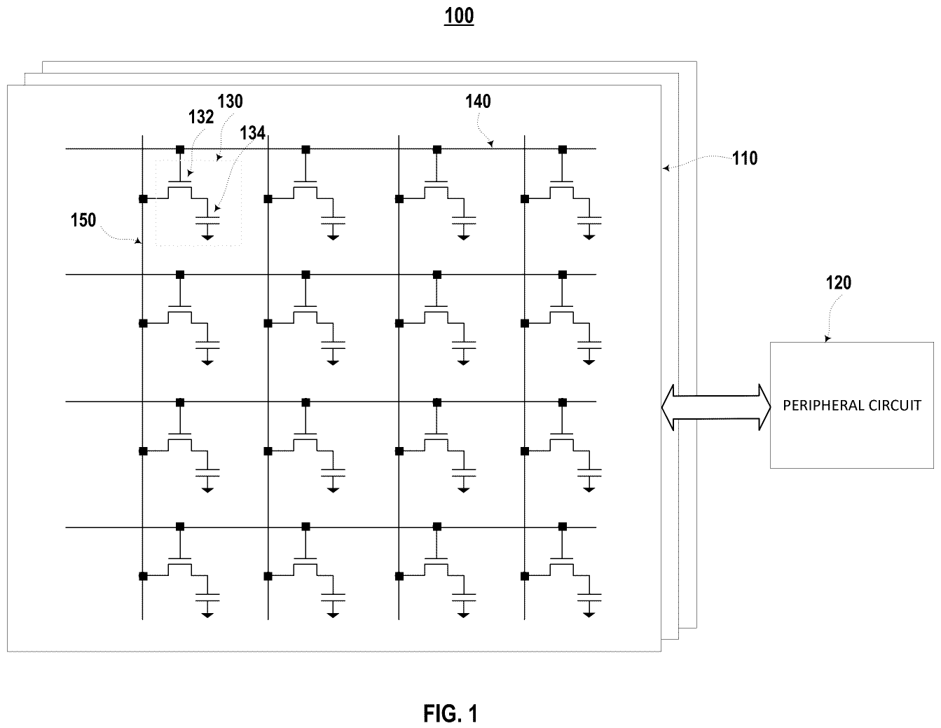

FIG. 1 illustrates a schematic diagram of a semiconductor device 100 including peripheral circuits and an array of memory cells each having a vertical transistor, according to some aspects of the present disclosure. Semiconductor device 100 can include a memory cell array 110 and peripheral circuits 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell. As shown in FIG. 1, memory cells 130 can be arranged in a two-dimensional (2D) array having rows and columns. Peripheral circuits 120 can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits 120 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Semiconductor device 100 can include word lines 140 coupling peripheral circuits 120 and memory cell array 110 for controlling the switch of vertical transistors 132 in memory cells 130 located in a row, as well as bit lines 150 coupling peripheral circuits 120 and memory cell array 110 for sending data to and/or receiving data from memory cells 130 located in a column. That is, each word line 140 is coupled to a respective row of memory cells 130, and each bit line 150 is coupled to a respective column of memory cells 130.

Consistent with the scope of the present disclosure, vertical transistors 132, such as vertical metal-oxide-semiconductor field-effect transistors (MOSFETs), can replace the conventional planar transistors as the pass transistors of memory cells 130 to reduce the area occupied by the pass transistors, the coupling capacitance, as well as the interconnect routing complexity, as described below in detail. As shown in FIG. 1, in some implementations, different from planar transistors in which the active regions are formed in the substrates, vertical transistor 132 includes a semiconductor body extending vertically (in the z-direction) above the substrate (not shown). That is, the semiconductor body can extend above the top surface of the substrate to expose not only the top surface of the semiconductor body, but also one or more side surfaces thereof. As shown in FIG. 1, for example, the semiconductor body can have a cuboid shape to expose four sides thereof. It is understood that the semiconductor body may have any suitable shape, such as a polyhedron shape or a cylinder shape. That is, the cross-section of the semiconductor body in the plan view (e.g., in the x-y plane) can have a square shape, a rectangular shape (or a trapezoidal shape), a circular (or an oval shape), or any other suitable shapes. It is understood that in consistent with the scope of the present disclosure, for semiconductor bodies that have a circular or oval shape of their cross-sections in the plan view, the semiconductor bodies may still be considered to have multiple sides, such that the gate structures are coupled with more than one side of the semiconductor bodies.

In some implementations, the semiconductor bodies can be formed from the substrate (e.g., by etching or epitaxy) and thus, have the same semiconductor material (e.g., silicon crystalline silicon) as the substrate (e.g., a silicon substrate). In some implementations, the semiconductor bodies can include metal oxide and semiconductor materials, such as low-temperature polysilicon (LTPS) and indium gallium zinc oxide. Specifically, semiconductor bodies can include one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

As shown in FIG. 1, vertical transistor 132 can also include a gate structure coupled with one or more lateral sides of semiconductor body. In other words, the active region of vertical transistor 132, i.e., the semiconductor body, can be at least partially surrounded by the gate structure. The ate structure can include a gate dielectric over one or more sides of the semiconductor body, e.g., coupled with four side surfaces of the semiconductor body as shown in FIG. 1. The gate structure can also include a gate electrode over and coupled with gate dielectric. The gate dielectric can include any suitable dielectric materials, such as silicon oxide, silicon nitride, silicon oxynitride, or high-k dielectrics. Gate electrodes can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

As shown in FIG. 1, vertical transistor 132 can further include a pair of a source and a drain (S/D, dope regions, a.k.a., source electrode and drain electrode) formed at the two ends of the semiconductor body in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by the gate structure in the vertical direction (the z-direction). As a result, one or more channels (not shown) of vertical transistor 132 can be formed in the semiconductor body vertically between the source and drain when a gate voltage applied to the gate electrode of the gate structure is above the threshold voltage of vertical transistor 132.

In some implementations, the vertical transistors 132 can be single-gate transistors, in which the gate structure may be located at a single lateral side of the semiconductor body, for example, for the purpose of increasing the transistor and memory cell density. In some other implementations, vertical transistor 132 can be a multi-gate transistor. That is, the gate structure can be laterally located at more than one side of the semiconductor body to form more than one gate, such that more than one channel can be formed between the source and drain in operation. That is, different from the planar transistor that includes only a single planar gate (and resulting in a single planar channel), vertical transistor 132 shown in FIG. 1 can include multiple vertical gates on multiple lateral sides of the semiconductor body due to the semiconductor structure of semiconductor body and gate structure that locates on the multiple lateral sides of the semiconductor body. Compared with planar transistors, vertical transistor 132 shown in FIG. 1 can have a larger gate control area to achieve better channel control with a smaller subthreshold swing. During the off state, since the channel is fully depleted, the leakage current of vertical transistor 132 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and gate-all-around (GAA) vertical transistors.

As shown in FIG. 1, storage unit 134 can be coupled to the source or the drain of vertical transistor 132. Storage unit 134 can include any devices that are capable of storing binary data (e.g., 0 and 1), including but not limited to, capacitors for DRAM cells and FRAM cells, and PCM elements for PCM cells. Peripheral circuits 120 can be coupled to memory cell array 110 through bit lines 150, word lines 140, and any other suitable metal wirings. As described above, peripheral circuits 120 can include any suitable circuits for facilitating the operations of memory cell array 110 by applying and sensing voltage signals and/or current signals through word lines 140 and bit lines 150 to and from each memory cell 130. Peripheral circuits 120 can include various types of peripheral circuits formed using CMOS technologies.

In some implementations, storage unit 134 can be pillar capacitors which are formed after forming the vertical transistors 132. Both the outer and inner surfaces of a pillar capacitor can be utilized as effective capacitor areas. This structure can be utilized to achieve greater packing density in a semiconductor device. In some other implementations, storage unit 134 can be cup capacitors, which are formed before forming the vertical transistors 132. In such implementations, the high-temperature processes of forming the cup capacitors do not affect the formation of vertical transistors 132. Thus, metal oxide semiconductors can be employed as the channel structures of vertical transistors 132.

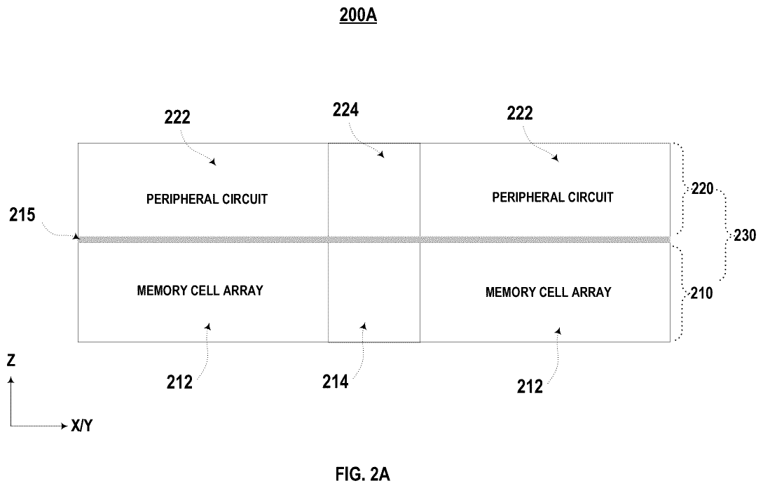

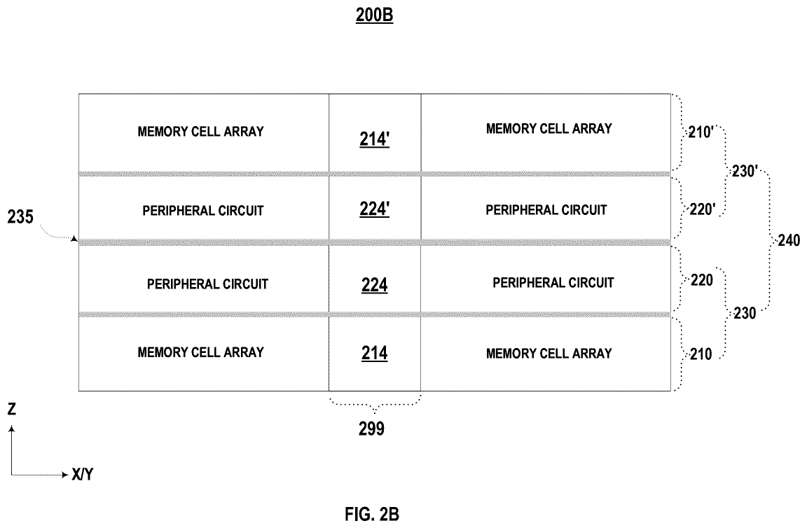

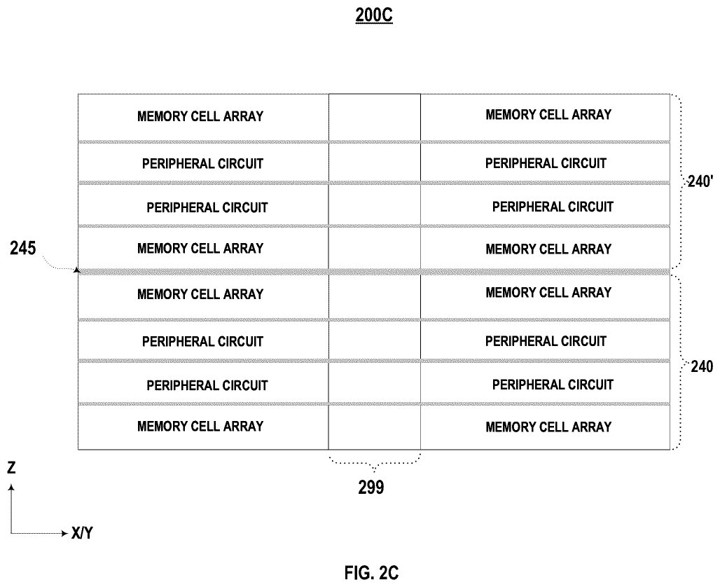

FIG. 2A illustrates a side view of a cross-section of a semiconductor device 200A, according to some aspects of the present disclosure. It is understood that FIG. 2A is for illustrative purposes only and may not necessarily reflect the actual device structure (e.g., interconnections) in practice. Semiconductor device 200A can include a memory array layer 210 including multiple memory cell arrays 212, and including first interconnection regions 214 between adjacent memory cell arrays 212. Semiconductor device 200A can further include a peripheral circuit layer 220 including the peripheral circuits 222 of the memory cell arrays 212, and including second interconnection regions 224 between adjacent peripheral circuits 222.

In some implementations, semiconductor device 200A represents an example of a bonded chip. That is, the two layers of semiconductor device 200A, i.e., the memory array layer 210 and the peripheral circuit layer 220, can be formed separately on different substrates and then joined at a bonding interface 215 to form a bonded chip. In some other implementations, semiconductor device 200A represents an example of a single chip. That is, the two layers of semiconductor device 200A, i.e., the memory array layer 210 and the peripheral circuit layer 220, can be formed on a same substrate. In some implementations, a thickness of the semiconductor device 200A is less than 12 μm.

FIG. 2B illustrates a side view of a cross-section of a semiconductor device 200B, according to some aspects of the present disclosure. It is understood that FIG. 2B is for illustrative purposes only and may not necessarily reflect the actual device structure (e.g., interconnections) in practice. Semiconductor device 200B can include two vertically stacked semiconductor stacks 230 and 230′, each of which can be the same as the semiconductor device 200A described above in connection with FIG. 2A. That is, the first semiconductor stack 230 can include a first memory array layer 210 and a first peripheral circuit layer 220, and the second semiconductor stack 230′ can include a second memory array layer 210′ and a second peripheral circuit layer 220′. In some implementations, a thickness of the first semiconductor stack 230 or the second semiconductor stack 230′ is less than 12 μm.

In some implementations, semiconductor device 200B is a bonded structure 240 formed by using a wafer-to-wafer hybrid bonding process to bond the first and second semiconductor stacks 230 and 230′. That is, before cutting the wafer 230/230′ into dies, the two entire wafers are hybrid bonded in a face-to-face manner. As such, the first and second peripheral circuit layers 220 and 220′ are bonded together at the bonding interface 235, and the first and second memory array layers 210 and 210′ sandwich the first and second peripheral circuit layers 220 and 220′, as shown in FIG. 2B. It is noted that, the first interconnection regions 214/214′ and the second interconnection regions 224/224′ are aligned with each other along the vertical direction to form a through interconnection region 299, realizing signal interconnect between memory cell arrays and peripheral circuits on different wafers.

FIG. 2C illustrates a side view of a cross-section of a semiconductor device 200C, according to some aspects of the present disclosure. It is understood that FIG. 2C is for illustrative purposes only and may not necessarily reflect the actual device structure (e.g., interconnections) in practice. Semiconductor device 200C can include two vertically stacked bonded structures 240 and 240′, each of which can be the same as the semiconductor device 200B described above in connection with FIG. 2B. That is, the first bonded structure 240 can include two semiconductor stacks each including a memory array layer and a peripheral circuit layer, and the second bonded structure 240′ can also include two semiconductor stacks each including a memory array layer and a peripheral circuit layer.

In some implementations, semiconductor device 200C is a bonded chip formed by using a wafer-to-wafer hybrid bonding process to bond the first and second bonded structures 240 and 240′. That is, before cutting the bonded structures 240/240′ into dies, the two entire bonded chips are hybrid bonded in a face-to-face manner at bonding interface 245. As such, the formed semiconductor device 200C can include four semiconductor stacks each including a memory array layer and a peripheral circuit layer. In some implementations, each of the four semiconductor stacks has a thickness of less than 12 μm. It is noted that, two semiconductor devices 200C can be further bonded together to form an 8-layer DRAM die stack, and so on, ultimately leading to a multi-layer stacked HBM structure.

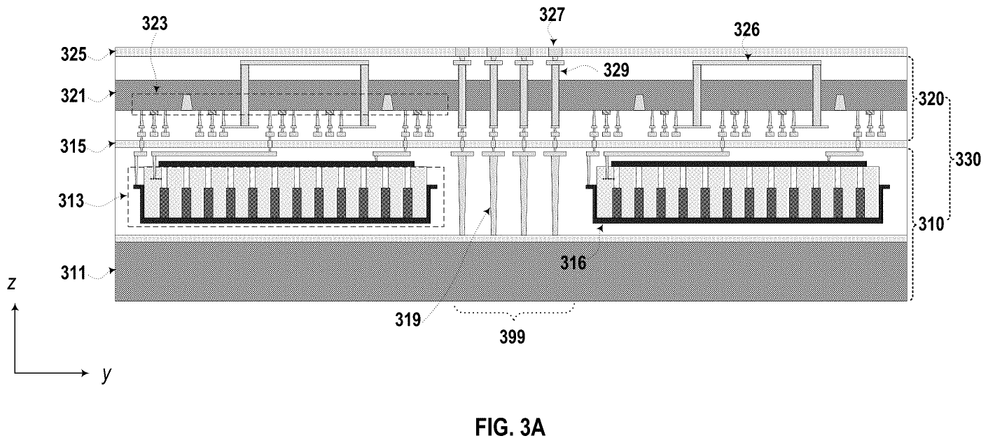

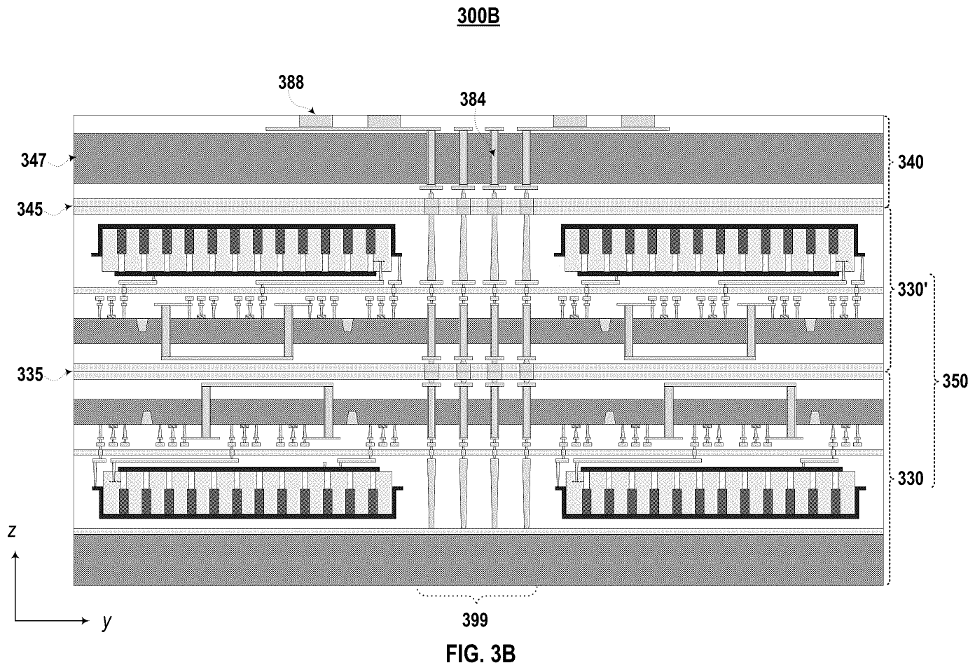

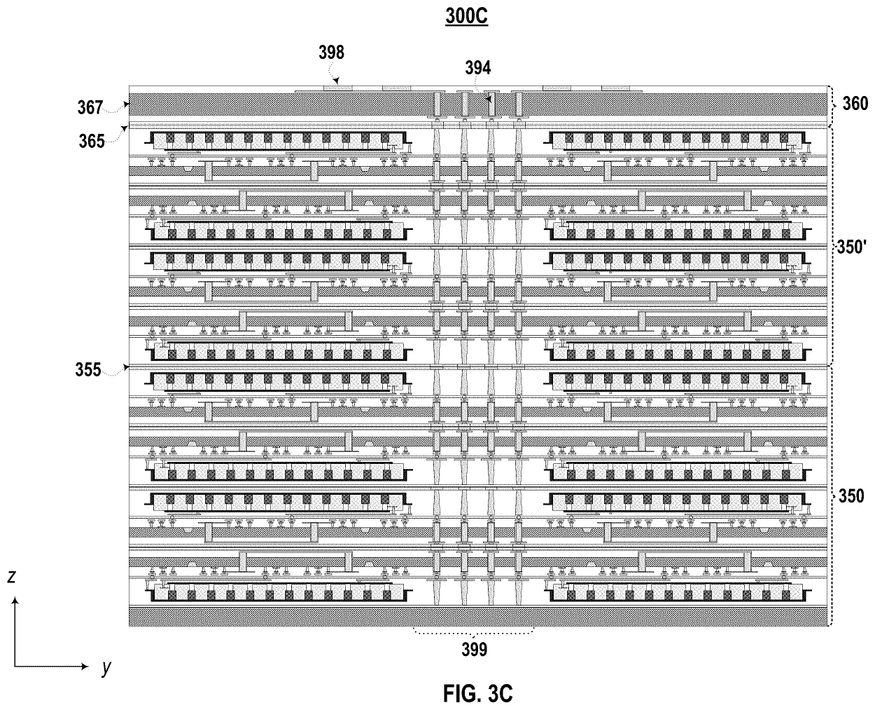

FIG. 3A illustrates a side view of a cross-section of a semiconductor device 300A, such as semiconductor device 200A shown in FIG. 2A, according to some aspects of the present disclosure.

In some implementations, the memory array layer 310 includes multiple memory cell arrays 313 provided in the form of arrays of DRAM cells on a substrate 311. Each memory cell array 313 can be an array of 1T1C cells each consisting of one transistor and one capacitor. In some implementations, each memory cell array 313 can include a transistor layer including an array of vertical transistors, and a storage layer including an array of vertical capacitors. That is, each DRAM cell includes a vertical capacitor and a vertical transistor coupled with the vertical capacitor. Each vertical capacitor can include a first electrode, a second electrode, and a dielectric layer formed between first and second electrodes. The first and second electrodes and the dielectric layer can extend vertically (in the z-direction), and the dielectric layer can be sandwiched between the first and second electrodes. In some implementations, the second electrodes can be connected with each other and function as a common electrode 316, while each first electrode can be coupled to a source of a respective vertical transistor in the same DRAM cell through a source node contact (SNC).

In some implementations, the first electrodes and/or the second electrode can include conductive materials including, but not limited to, W, Co, Cu, Al, TiN, TaN, polysilicon, silicide, or any combination thereof. In some implementations, the first electrodes and/or the second electrode can include a multiple-layer structure, each layer of the multiple-layer structure comprising one of TiN, TaN, carbon, polysilicon, metal, metal compounds, and silicide. In some implementations, the dielectric layer includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof.

In some implementations, each vertical transistor (e.g., a MOSFET) is configured to switch a respective DRAM cell. In some implementations, each first transistor includes a semiconductor body (i.e., the active region in which multiple channels can form) extending vertically (in the z-direction), and a gate structure located at one or more lateral sides of semiconductor body. In some implementations, the semiconductor body can include any suitable semiconductor material, such as monocrystalline silicon, polycrystalline silicon, or silicon-germanium. In some other implementations, the semiconductor body can include a metal oxide semiconductor material, such as InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc.

In some implementations, the semiconductor body extends in a vertical direction (the z-direction), and includes a source and a drain disposed at the two ends (the upper end and lower end) of the semiconductor body, respectively. The source and drain can be doped with N-type dopants (e.g., P or As) or P-type dopants (e.g., B or Ga) at a desired doping level. In some implementations, the source is coupled to a corresponding vertical capacitor through the SNC, and the drain is coupled to a bit line, which extends in the lateral direction (the y-direction). In some implementations, the SNC may include a heavily doped polysilicon to form an Ohmic contact with the source ends of the vertical transistors to decrease contact resistance.

In some implementations, the gate structure (not shown in FIG. 3A) of each vertical transistor includes a gate dielectric and a gate electrode. In some implementations, the gate dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the gate electrode includes conductive materials including, but not limited to, W, Co, Cu, Al, TiN, TaN, polysilicon, silicide, or any combination thereof. In some implementations, the gate electrode includes multiple conductive layers, such as a W layer over a TiN layer. In one example, the gate structure may be a “gate oxide/gate poly” gate in which the gate dielectric includes silicon oxide, and the gate electrode includes doped polysilicon. In another example, the gate structure may be a high-k metal gate (HKMG) in which the gate dielectric includes a high-k dielectric, and the gate electrode includes a metal.

In some implementations, the gate electrode may be part of a word line or extend in the word line direction (the x-direction) as a word line. Each word line can extend in the word line direction (the x-direction), and be coupled to a row of DRAM cells. That is, the bit line and the word line can extend in two perpendicular lateral directions, and the semiconductor body of each vertical transistor can extend in the vertical direction perpendicular to the two lateral directions in which the bit line and the word line extend.

In some implementations, the memory array layer 310 can further include one or more interconnect layers including interconnect structures to electrically connect the word lines, the bit lines, the electrodes of capacitors, etc., to transfer electrical signals. In some implementations, the one or more interconnect layers can include lateral interconnect lines and vertical interconnect access (VIA) contacts. In some implementations, as shown in FIG. 3A, one or more first interconnection structures 319 can be located between adjacent memory cell arrays 313 and extend through the memory array layer 310. In some implementations, the one or more interconnect layers can also include local interconnects, such as bit line contacts, word line contacts, and capacitor contacts.

As used herein, the term “interconnects” can broadly include any suitable types of interconnects, such as middle-end-of-line (MEOL) interconnects and back-end-of-line (BEOL) interconnects. The one or more interconnect layers can further include one or more interlayer dielectric (ILD) layers (also known as “intermetal dielectric (IMD) layers”) in which the interconnect lines and VIA contacts can form. That is, the one or more interconnect layers can include interconnect lines and VIA contacts in multiple ILD layers. The interconnects in the one or more interconnect layers can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

In some implementations, the peripheral circuit layer 320 can include a plurality of transistors 323 (e.g., planar transistors and/or semiconductor transistors, not shown) formed on or in a semiconductor layer 321. Trench isolations (e.g., shallow trench isolations (STIs), not shown) and doped regions (e.g., wells, sources, and drains of transistors, not shown) can be formed on or in the semiconductor layer 321. In some implementations, the peripheral circuit layer 320 can include one or more interconnect layers including interconnect structures to electrically connect the transistors 323 to transfer electrical signals. In some implementations, the one or more interconnect layers can include lateral interconnect lines and VIA contacts. In some implementations, as shown in FIG. 3A, one or more second interconnection structures 329 can extend through the semiconductor layer 321. In some implementations, one or more bridge contact structure 326 can laterally extend on a side of the semiconductor layer 321 opposite to the transistors 323, and vertically extend through the semiconductor layer 321 twice to interconnect two of the transistors 323. In some implementations, the peripheral circuit layer 320 can further include a pad-out layer 325 including pad contacts 327.

In some implementations, the memory array layer 310 and the peripheral circuit layer 320 can be bonded together at the bonding interface 315 to form a semiconductor stack 330. The bonding interface 315 can be an interface between the memory array layer 310 and the peripheral circuit layer 320 formed by any suitable bonding technologies, such as hybrid bonding, anodic bonding, fusion bonding, transfer bonding, adhesive bonding, eutectic bonding, to name a few. The first interconnection structures 319 can be joined with the second interconnection structures 329 at the bonding interface 315 to form through interconnects in through interconnection region 399.

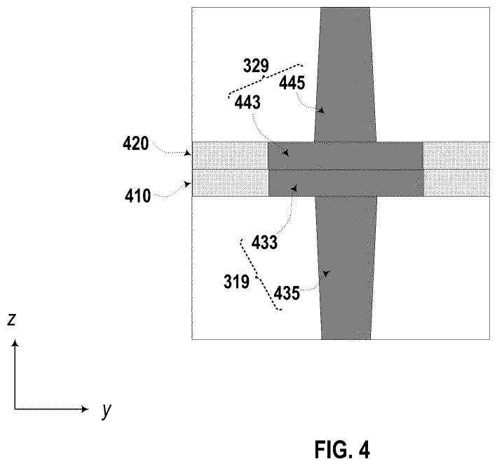

FIG. 4 illustrates a schematic enlarged cross-sectional view of the joined portion of the first and second interconnection structures 319 and 329, according to some implementations of the present disclosure. In some implementations, the first interconnection structure 319 includes a first conductive pad 433 in a first bonding layer 410, and a first VIA structure 435 extending though the memory array layer 310. The second interconnection structure 329 includes a second conductive pad 443 in a second bonding layer 420, and a second VIA structure 445 extending though the peripheral circuit layer 320. The first conductive pad 433 is in contact with the second conductive pad 443 due to hybrid bonding of the first bonding layer 410 and the second bonding layer 420. In some implementations, the first bonding layer 410 comprises a first carbon nitride layer where the first conductive pad 433 is embedded, and the second bonding layer 420 comprises a second carbon nitride layer where the second conductive pad 443 is embedded. In some implementations, the first bonding layer 410 comprises a first silicon oxide layer where the first conductive pad is 433 embedded, and the second bonding layer 420 comprises a second silicon oxide layer where the second conductive pad 443 is embedded.

FIG. 3B illustrates a side view of a cross-section of a semiconductor device 300B, such as 200B shown in FIG. 2B, according to some aspects of the present disclosure.

In some implementations, semiconductor device 300B can include two semiconductor stacks 330 and 330′, each of which has the same structure as the semiconductor device 300A as described above in connection with FIG. 3A. In some implementations, a first semiconductor stack 330 and a second semiconductor stack 330′ can be bonded with each other in a face-to-face manner to form a bonded structure 350. The through interconnects of the first and second semiconductor stacks 330 and 330′ in the through interconnection region 399 can be connected at bonding interface 335. The joined portion of the through interconnects can be similar to the structure shown in FIG. 4 and the corresponding descriptions above.

In some implementations, as shown in FIG. 3B, the original substrate of the second semiconductor stack 330′ can be removed, and a pad-out layer 340 can be bonded to a backside of the second semiconductor stack 330′ at bonding interface 345. In some implementations, the pad-out layer 340 can include a substrate 347 and through contacts 384 extending through the substrate 347. The pad-out layer 340 can further include one or more interconnect layers including interconnect structures to electrically connect the through contacts 384 to transfer electrical signals. In some implementations, the one or more interconnect layers can include lateral interconnect lines, VIA contacts, and contact pads 388. In some implementations, as shown in FIG. 3B, the through contacts 384 can be located in the through interconnection region 399 and coupled with the interconnects of the second semiconductor stack 330′ through the bonding interface 345. The joined portion of the through interconnects and the through contacts 384 can be similar to the structure shown in FIG. 4 and the corresponding descriptions above.

FIG. 3C illustrates a side view of a cross-section of a semiconductor device 300C, such as 200C shown in FIG. 2C, according to some aspects of the present disclosure.

In some implementations, semiconductor device 300C can include two bonded structures 350 and 350′, each of which has the same structure as the semiconductor device 300B as described above in connection with FIG. 3B. In some implementations, a first bonded structure 350 and a second bonded structure 350′ can be bonded with each other in a face-to-face manner. The through interconnects of the first and second bonded structures 350 and 350′ in the through interconnection region 399 can be connected at bonding interface 355. The joined portion of the through interconnects can be similar to the structure shown in FIG. 4 and the corresponding description above.

In some implementations, as shown in FIG. 3C, the original substrate of the second bonded structure 350′ can be removed, and a pad-out layer 360 can be bonded to a backside of the second bonded structure 350′ at bonding interface 365. In some implementations, the pad-out layer 360 can include a substrate 367 and through contacts 394 extending through the substrate 367. The pad-out layer 360 can further include one or more interconnect layers including interconnect structures to electrically connect the through contacts 394 to transfer electrical signals. In some implementations, the one or more interconnect layers can include lateral interconnect lines, VIA contacts, and contact pads 398. In some implementations, as shown in FIG. 3C, the through contacts 394 can be located in the through interconnection region 399 and coupled with the interconnects of the second bonded structure 350′ through the bonding interface 365. The joined portion of the through interconnects and the through contacts 394 can be similar to the structure shown in FIG. 4 and the corresponding descriptions above.

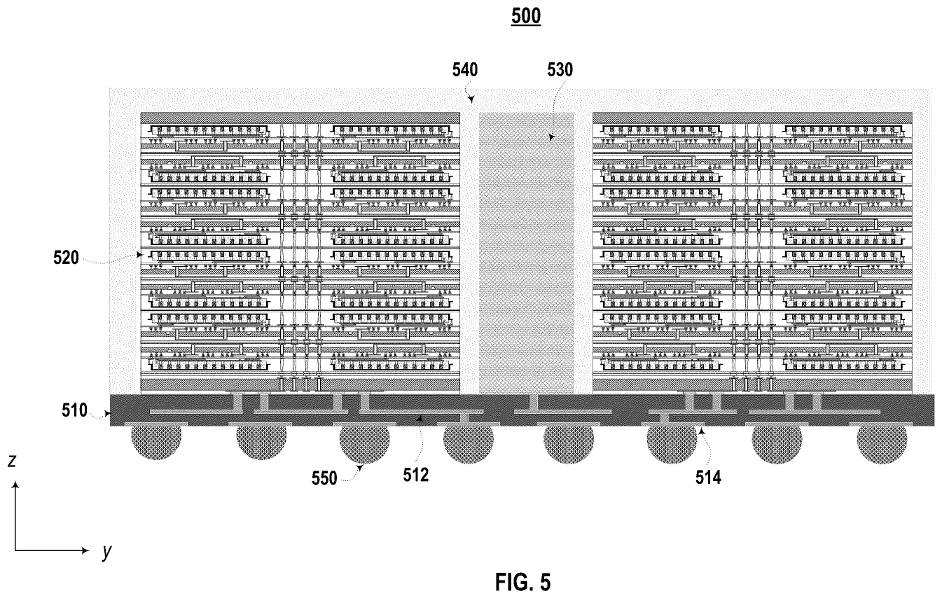

FIG. 5 illustrates a side view of a cross-section of a memory device 500, according to some implementations of the present disclosure. Memory device 500 can be a DRAM device. As shown in FIG. 5, the memory device 500 can be a chip packing structure including a base substrate 510, one or more die stacks 520 and a memory control circuit 530 on a first side of the base substrate 510, a mold compound layer 540 fully covering the one or more die stacks 520 and the memory control circuit 530, and a ball grid array (BGA) 550 on a second side of the base substrate 510 opposite to the first side.

The base substrate 510 can be any suitable semiconductor substrate having any suitable structure, such as a monocrystalline single-layer substrate, a polycrystalline silicon (polysilicon) single-layer substrate, a polysilicon and metal multi-layer substrate, etc. The base substrate 510 can include conductive wiring structures 512 embedded therein. The conductive wiring structures 512 can include any suitable conductive interconnection structures, such as conductive vias and patterned conductive layers, etc. The base substrate 510 can further include an array of ball pads 514 on a bottom surface to accept the BGA 550 for both electrical connections and/or mechanically fasten connections. The conductive wiring structures 512 and the array of ball pads 514 can include any suitable conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art.

In some implementations, the one or more die stacks 520 can include one or more of portions of the semiconductor devices 300A/300B/300C shown in FIGS. 3A-3C, respectively, as described above in detail. In some implementations, the entire wafers of the semiconductor devices 300A/300B/300C can be cut to form multiple functional dies, and one or more of the functional dies can be stacked to form the die stack 520. The one or more die stacks 520 can be attached to the base substrate 510 by an adhesive film (not shown). The adhesive film can be any suitable die-attached film (DAF). In some implementations, the contact pads of the pad-out layer of the semiconductor devices 300A/300B/300C (also referred to as bond pads, redistribution pads, or similar structures as known to those skilled in the art) can be coupled with the conductive interconnection structures of the conductive wiring structures 512 of the base substrate 510.

In some implementations, the memory control circuit 530 is coupled to the one or more die stacks 520 and is configured to control and coordinate the one or more die stacks 520, according to some implementations. The memory control circuit 530 can be configured to coordinate the one or more die stacks 520 and to control operations of multiple memory cell arrays within the one or more die stacks 520. In some implementations, the memory control circuit 530 can also be configured to manage various functions with respect to the data stored or to be stored in the one or more die stacks 520 including, but not limited to refresh and timing control, command/request translation, buffer and schedule, and power management. In some implementations, the memory control circuit 530 is further configured to determine the maximum memory capacity and speed, memory particle data depth and data width, and other important parameters.

In some implementations, a plurality of signal wires (not shown) can be electrically connected between the plurality of bond pads of the one or more die stacks 520, the memory control circuit 530, and the conductive wiring structures 512. As such, the one or more die stacks 520 and/or the memory control circuit 530 can be coupled with the BGA 550 and connected to an external device, such as a printed circuit board (PCB). In some implementations, the BGA 550 can include a plurality of solder balls on the bottom surface of the base substrate 510 and mechanically connected to the ball pads 514. That is, the solder balls are configured for electrically connecting the memory device 500 to a PCB to provide transmission of electric signals between a circuit on the PCB and the one or more die stacks 520 and/or memory control circuit 530 of the memory device 500. In some implementations, the solder balls can comprise any suitable metal material, such as Aluminum (Al), Antimony (Sb), Arsenic (As), Bismuth (Bi), Cadmium (Cd), Co, Cu, Ni, Au, Ag, Indium (In), Iron (Fe), Lead (Pb), Phosphorus (P), Tin (Sn), Sulfur(S), Zinc (Zn), Germanium (Ge), etc., and any suitable alloy thereof.

As shown in FIG. 5, the memory device 500 can further include a mold compound layer 540 on the base substrate 510 to fully cover the one or more die stacks 520 and memory control circuit 530. In some implementations, the mold compound layer 540 can be a thermally curable epoxy mold compound or a thermally curable epoxy mold resin. For example, the mold compound layer 540 comprises an inorganic filler (for example, silica), an epoxy resin, a curing agent, a flame retardant, a curing promoter, a release agent, and any other suitable components as known to those skilled in the art.

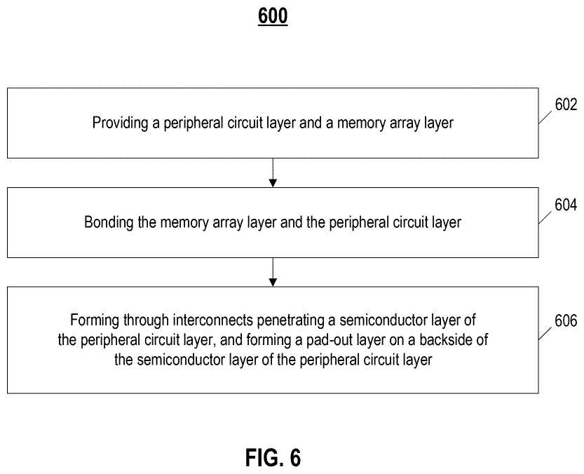

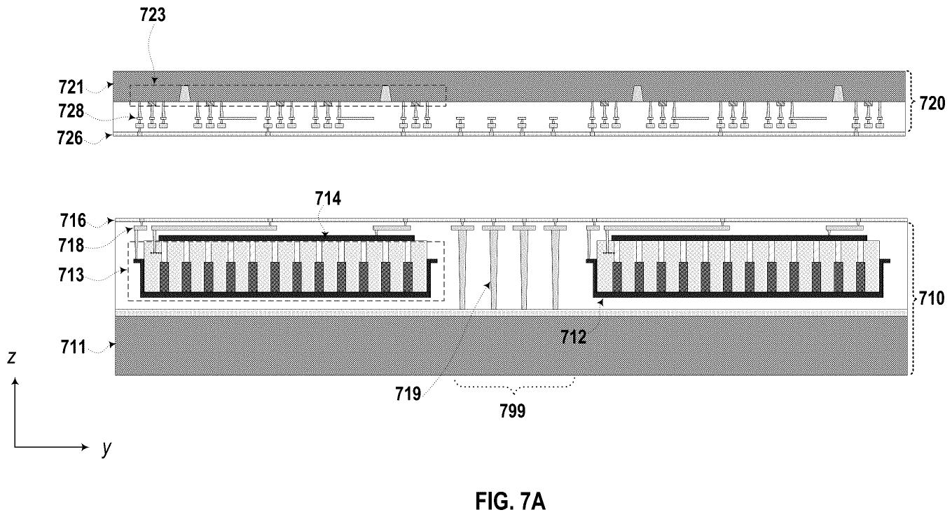

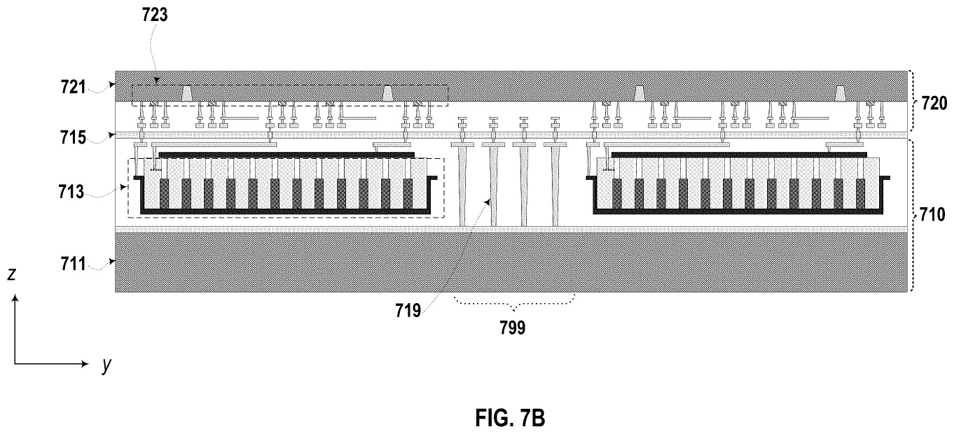

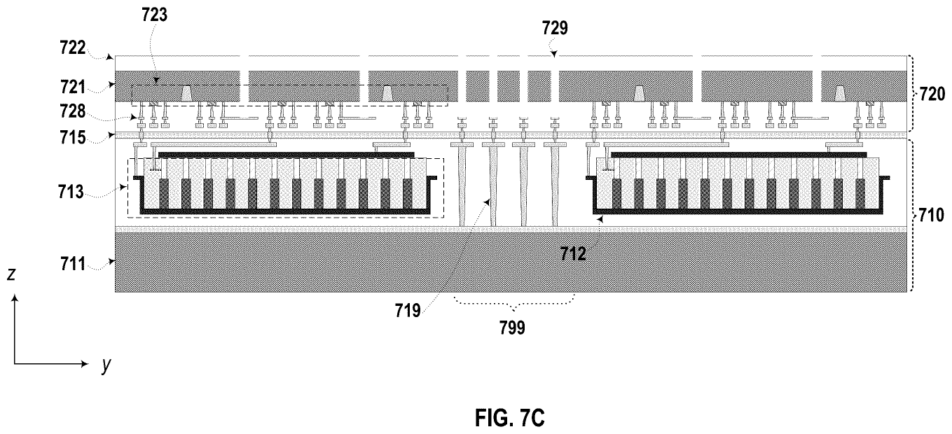

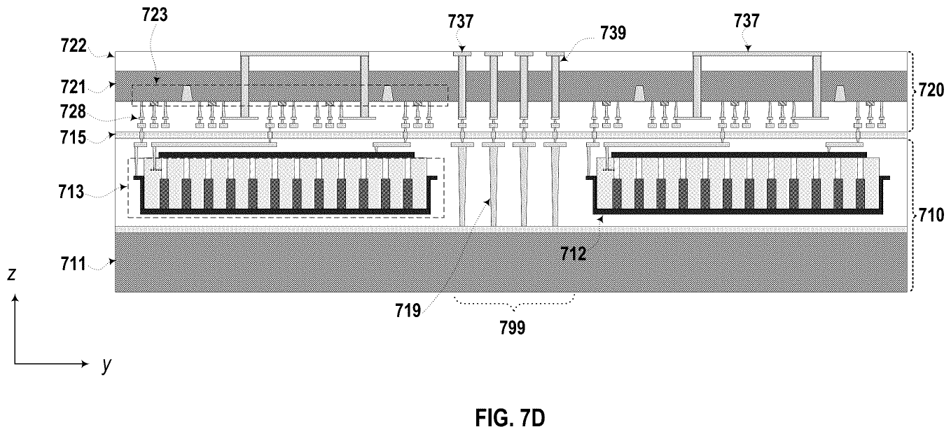

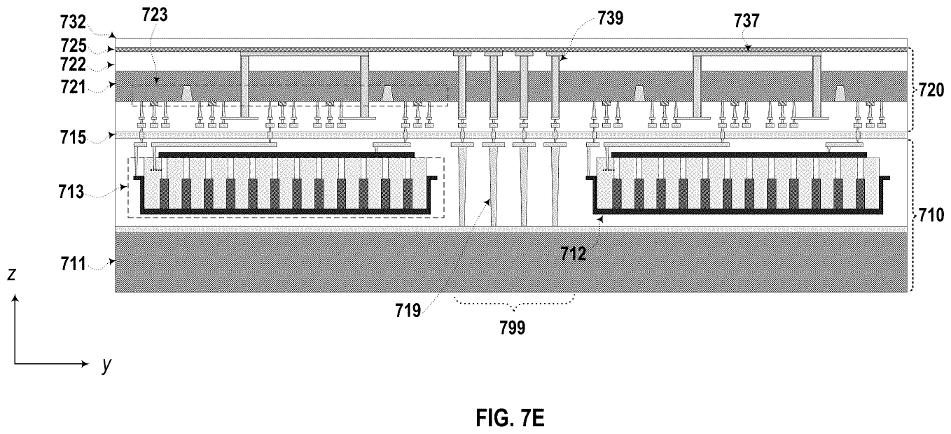

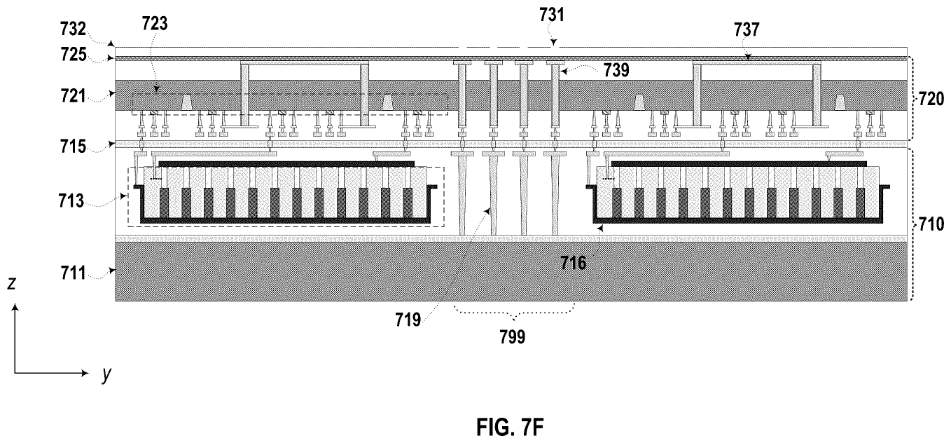

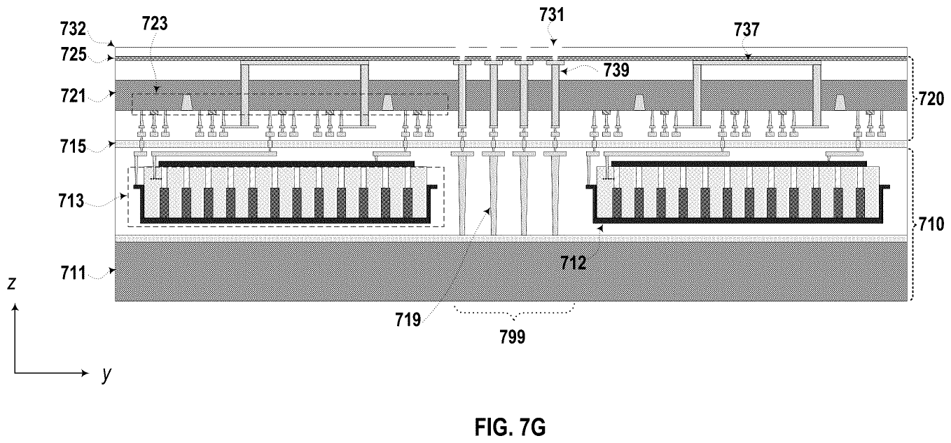

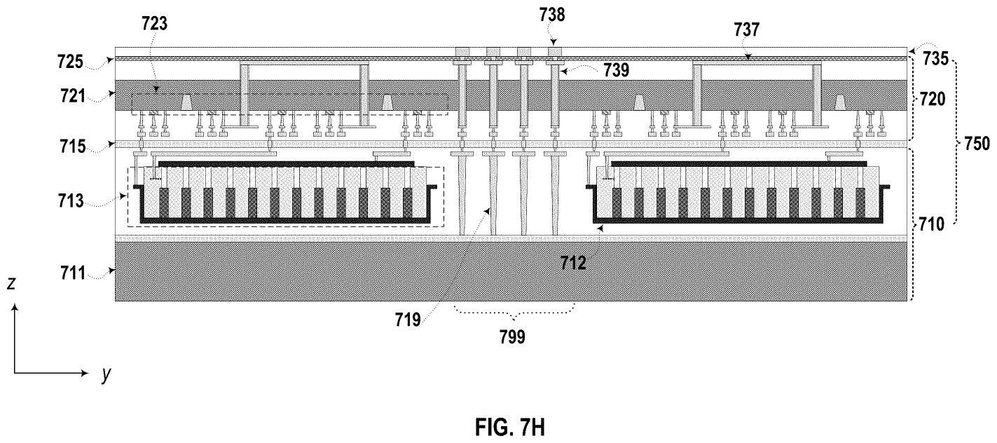

FIG. 6 illustrates a flowchart of a fabricating method 600 for forming a semiconductor structure, according to some implementations of the present disclosure. FIGS. 7A-7H illustrate schematic views of a semiconductor device at certain fabricating stages of the method 600 shown in FIG. 6, according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIG. 6, method 600 can start at operation 602, in which a peripheral circuit layer and a memory array layer can be provided. FIG. 7A illustrates a schematic side cross-sectional view of the semiconductor structures in the y-z plane after operation 602 of method 600.

In some implementations, as shown in FIG. 7A, forming the peripheral circuit layer 720 includes forming a peripheral circuit including a plurality of transistors 723 on a semiconductor layer 721. In some implementations, an interconnect layer 728 is formed above the peripheral circuit. The interconnect layer 728 can include a plurality of interconnects in one or more ILD layers.

In some implementations, a plurality of transistors 723 are formed on semiconductor layer 721. The transistors can be formed by a plurality of processes including, but not limited to, photolithography, dry/wet etch, thin film deposition, thermal growth, implantation, chemical mechanical polishing (CMP), and any other suitable processes. In some implementations, doped regions are formed in the semiconductor layer 721 by ion implantation and/or thermal diffusion, which function, for example, as the source and drain of the transistors 723. In some implementations, isolation regions (e.g., STIs) are also formed in the semiconductor layer 721 by wet/dry etch and thin film deposition. The transistors 723 can form one or more peripheral circuits on the semiconductor layer 721.

In some implementations, an interconnect layer 728 can be formed above the peripheral circuits having transistors 723. Interconnect layer 728 can include interconnects of MEOL and/or BEOL in a plurality of ILD layers to make electrical connections with the transistors 723. In some implementations, interconnect layer 728 includes multiple ILD layers and interconnects therein formed in multiple processes. For example, the interconnects in interconnect layers 728 can include conductive materials deposited by one or more thin film deposition processes including, but not limited to, chemical vapor deposition (CVD), physical vapor deposition (PVD), atomic layer deposition (ALD), electroplating, electroless plating, or any combination thereof. Fabrication processes to form the interconnects can also include photolithography, CMP, wet/dry etch, or any other suitable processes. The ILD layers can include dielectric materials deposited by one or more thin film deposition processes including, but not limited to, CVD, PVD, ALD, or any combination thereof. The ILD layers and interconnects illustrated in FIG. 7A can be collectively referred to as interconnect layer 728.

In some implementations, a bonding layer 726 including multiple bonding contacts is formed above the peripheral circuit (and the interconnect layer 728). As illustrated in FIG. 7A, the bonding layer 726 is formed above the interconnect layer 728 and the peripheral circuits having transistors 723. Bonding layer 726 can include a plurality of bonding contacts surrounded by dielectrics. In some implementations, a dielectric layer (e.g., ILD layer) is deposited on the top surface of interconnect layer 728 by one or more thin film deposition processes including, but not limited to, CVD, PVD, ALD, or any combination thereof. The bonding contacts then can be formed through the dielectric layer and in contact with the interconnects in interconnect layer 728 by first patterning contact holes through the dielectric layer using a patterning process (e.g., photolithography and dry/wet etch of dielectric materials in the dielectric layer). The contact holes can be filled with a conductor (e.g., Cu). In some implementations, filling the contact holes includes depositing a barrier layer, an adhesion layer, and/or a seed layer before depositing the conductor.

In some implementations, forming the memory array layer 710 can comprise forming arrays of DRAM cells 713 each including a vertical transistor and a storage unit on a substrate 711. The substrate 711 can include a carrier substrate. The storage unit can include a capacitor or a PCM element. In some implementations, a capacitor is formed to be coupled to the vertical transistor in the respective memory cell. In some implementations, forming arrays of memory cells comprises forming a transistor layer and forming a storage layer. In some implementations, forming the transistor layer includes forming arrays of semiconductor bodies each extending vertically. In some implementations, fabricating processes of forming the arrays of semiconductor bodies can include one or more of deposition processes, lithography processes, epitaxial growing processes, dry etching and/or wet etching processes, and/or any other suitable processes. In some implementations, each semiconductor body can function as a channel of the vertical transistor. In some implementations, both ends of each semiconductor body can be doped to form source/drain of the vertical transistor. In some implementations, an implantation process and/or thermal diffusion process are performed to dope P-type dopants or N-type dopants to one or more ends of the semiconductor bodies to form sources/drains.

In some implementations, forming the transistor layer further comprises forming gate structures on lateral sides of the semiconductor bodies. In some implementations, to form the gate structure, a gate dielectric is formed over the exposed part of the semiconductor body, a conductive layer is deposited over the gate dielectric, and the conductive layer is patterned to form a gate electrode over the gate dielectric. It is noted that, each formed gate structure can be on one or more lateral sides of a corresponding semiconductor body, forming any suitable type of transistor, such as a single-gate transistors, a double-gate transistors, a gate-all-around (GAA) transistor, or a gate-partially-around (GPA) transistor. In some implementations, the patterned conductive layers can become word lines each extending in the word line direction (the x-direction) and being separated by adjacent trenches, and parts of patterned conductive layers that are over the gate dielectrics can become gate electrodes.

In some implementations, forming the storage layer can including forming arrays of storage units in contact with the semiconductor bodies, e.g., one doped end thereof. The storage unit can include a capacitor or a PCM element. In some implementations, to form a storage unit that is a capacitor, a first electrode is formed on the one doped end of the semiconductor body, a capacitor dielectric is formed on the first electrode, and a second electrode is formed on the capacitor dielectric. In some implementations, fabricating processes of forming the first electrode, the capacitor dielectric, and the second electrode can include one or more thin film deposition processes (e.g., CVD, PVD, ALD, etc.), patterning and etching processes, and/or any other suitable processes. In some implementations, the second electrodes of the capacitors can be coupled to a common conductive layer 712 to function as a common electrode. In some implementations, the common conductive layer 712 comprises a main lateral plate in contact with the plurality of second electrodes, a vertical plate in contact with an edge of the main lateral plate, and a lateral landing portion in contact with the vertical plate and a capacitor contact.

In some implementations, an interconnect layer 718 including bit lines is formed above the arrays of memory cells. As illustrated in FIG. 7A, an interconnect layer 718 can be formed above DRAM cells 713. Interconnect layer 718 can include interconnects of MEOL and/or BEOL in a plurality of ILD layers to make electrical connections with DRAM cells 713. In some implementations, interconnect layer 718 includes multiple ILD layers and interconnects therein formed in multiple processes. In some implementations, one or more through interconnects 719 can be formed in a through interconnection region 799 between adjacent arrays of DRAM cells 713 and extending through the memory array layer 710. In some implementations, the through interconnects 719 and the interconnects in interconnect layers 718 can include conductive materials deposited by one or more thin film deposition processes including, but not limited to, CVD, PVD, ALD, electroplating, electroless plating, or any combination thereof. Fabrication processes to form the interconnects can also include photolithography, CMP, wet/dry etch, or any other suitable processes. The ILD layers and interconnects illustrated in FIG. 7A can be collectively referred to as interconnect layer 718.

In some implementations, forming the interconnect layer 718 includes forming bit lines on the doped source ends of the DRAM cells 713. As illustrated in FIG. 7A, bit line 714 can be formed on the source ends by patterning and etching a trench aligned with a column of source ends along the bit line direction (the y-direction) using lithography and etching processes and depositing conductive materials to fill the trench using thin film deposition processes. As a result, bit line 714 and capacitor having the first and second electrodes and the capacitor dielectric can be formed on opposite sides of the semiconductor body and coupled to opposite ends of the semiconductor body. It is understood that the through interconnects 719, and additional local interconnects, such as word line contacts, capacitor contacts, and bit line contacts may be similarly formed as well.

In some implementations, a bonding layer 716 including can include bonding contacts can be formed above the arrays of DRAM cells 713 and the interconnect layer 718. As illustrated in FIG. 7A, a bonding layer 716 is formed above interconnect layer 718 and DRAM cells 713. Bonding layer 716 can include a plurality of bonding contacts surrounded by dielectrics. In some implementations, a dielectric layer (e.g., ILD layer) is deposited on the top surface of interconnect layer 718 by one or more thin film deposition processes including, but not limited to, CVD, PVD, ALD, or any combination thereof. Bonding contacts can then be formed through the dielectric layer and in contact with the interconnects in interconnect layer 718 by first patterning contact holes through the dielectric layer using a patterning process (e.g., photolithography and dry/wet etch of dielectric materials in the dielectric layer). The contact holes can be filled with a conductor (e.g., Cu). In some implementations, filling the contact holes includes depositing a barrier layer, an adhesion layer, and/or a seed layer before depositing the conductor.

Referring back to FIG. 6, method 600 proceeds to operation 604, in which the memory array layer and the peripheral circuit layer are bonded in a face-to-face manner, such that the first array of memory cells is coupled to the peripheral circuit across a bonding interface. FIG. 7B illustrates a schematic side cross-sectional view of a semiconductor structure in the y-z plane after operation 604 of method 600.

In some implementations, the bonding of the memory array layer 710 and the peripheral circuit layer 720 can include hybrid bonding. In some implementations, the bonding contacts in the bonding layer 716 of the memory array layer 710 are in contact with the bonding contacts in the bonding layer 726 of the peripheral circuit layer 720 at the bonding interface 715 after the bonding. In some implementations, the peripheral circuit layer 720 is above the memory array layer 710 after the bonding.

As illustrated in FIG. 7A, the semiconductor layer 721 and components formed thereon (e.g., the peripheral circuits) are flipped upside down. As illustrated in FIG. 7A, bonding layer 726 facing down is bonded with bonding layer 716 facing up, i.e., in a face-to-face manner, thereby forming a bonding interface 715 shown in FIG. 7B. In some implementations, a treatment process, e.g., a plasma treatment, a wet treatment, and/or a thermal treatment, is applied to the bonding surfaces prior to the bonding. After the bonding, the bonding contacts in the bonding layers 716 and 726 are aligned and in contact with one another, such that DRAM cells 713 can be electrically connected to the peripheral circuits including the transistors 723 across the bonding interface 715.

Method 600 proceeds to operation 606, in which through interconnects can be formed to penetrate the semiconductor layer of the peripheral circuit layer, and a pad-out layer is formed on the backside of the semiconductor layer of the peripheral circuit layer. FIGS. 7C-7G each illustrates a schematic side cross-sectional view of a semiconductor structure in the y-z plane at a certain stage of operation 606 of method 600. FIG. 7H illustrates a schematic side cross-sectional view of a semiconductor stack 750 in the y-z plane after operation 606 of method 600.

As illustrated in FIG. 7C, a patterned mask layer 722 can be formed on the semiconductor layer 721. Using the patterned mask layer 722, a plurality of openings 729 can be formed to penetrate the semiconductor layer 721 to expose portions of the interconnects of the interconnect layer 728 of the peripheral circuit layer 720. As illustrated in FIG. 7D, a plurality of through interconnects 739 can be formed in the openings 729. In some implementations, some through interconnects 739 in the through interconnection region 799 can be coupled with the through interconnects 719 in the memory array layer 710. Some other interconnects 739 can be coupled with the interconnects in the interconnect layer 728 of the peripheral circuit layer 720. In some implementations, a patterned conductive layer 737 including bridge contact structures and/or contact pads can be formed on the patterned mask layer 722 to be in contact with the through interconnects 739. In some implementations, the through interconnects 739 and the patterned conductive layer 737 can include conductive materials including, but not limited to, W, Co, Cu, Al, doped silicon, silicides, or any combination thereof. The patterned mask layer 722 can include dielectric materials including, but not limited to, silicon oxide, silicon nitride, silicon oxynitride, low-k dielectrics, or any combination thereof.

As shown in FIG. 7E, an etch stop layer 725 can be formed on the patterned conductive layer 737, and an insulating layer 732 can be formed on the etch stop layer 725. In some implementations, the etch stop layer 725 and the insulating layer 732 can have different dielectric materials having different etching rates in a same etching process. In some implementations, the etching rate of the dielectric material of the etch stop layer 725 can be less than the etching rate of the dielectric material of the insulating layer 732. For example, the etch stop layer 725 can include silicon nitride, while the insulating layer 732 can include silicon oxide. As shown in FIG. 7F, the insulating layer 732 can be patterned by using a wet etch process to form openings 731 to expose portions of the etch stop layer 725. As shown in FIG. 7G, a dry etch process, such as a punch etching, can be performed on the exposed portions of the etch stop layer 725 in the bottom of the openings 731, such that the contact pads of the patterned conductive layer 737 are exposed by the openings 731. As illustrated in FIG. 7H, a conductive material can be filled in the opening 731 by a deposition process to form pad contacts 738. As such, the pad-out layer 735 including the pad contacts 738 embedded in the insulating layer 732 is formed on the etch stop layer 725. In some implementations, the pad contacts 738 can include conductive materials including, but not limited to, W, Co, Cu, Al, doped silicon, silicides, or any combination thereof.

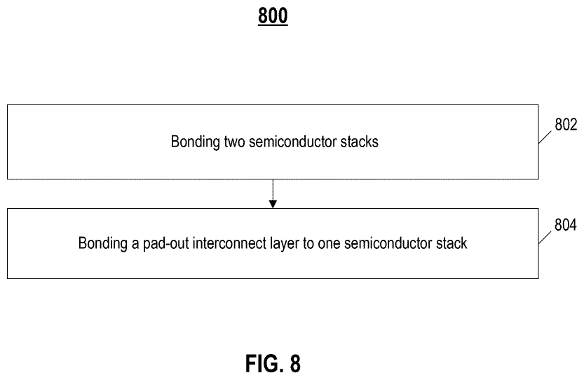

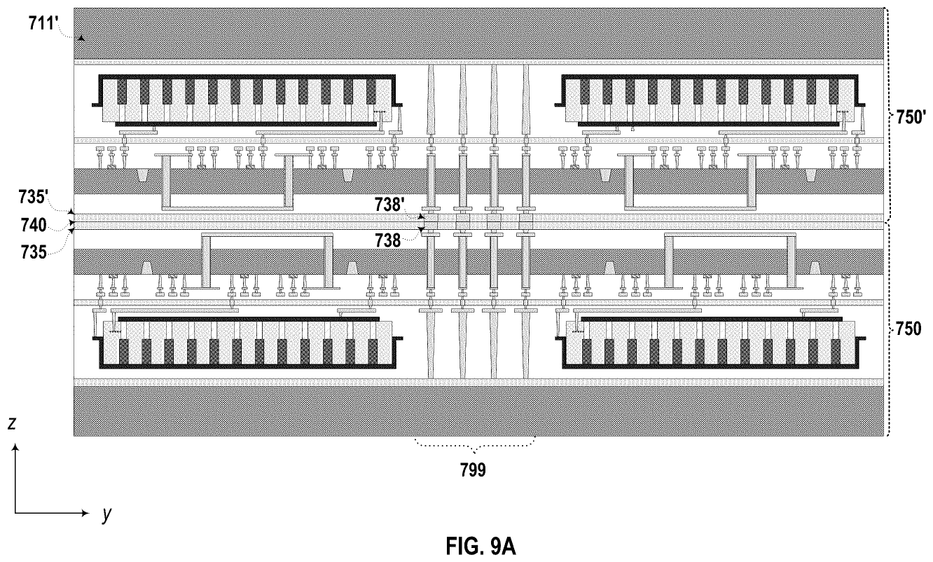

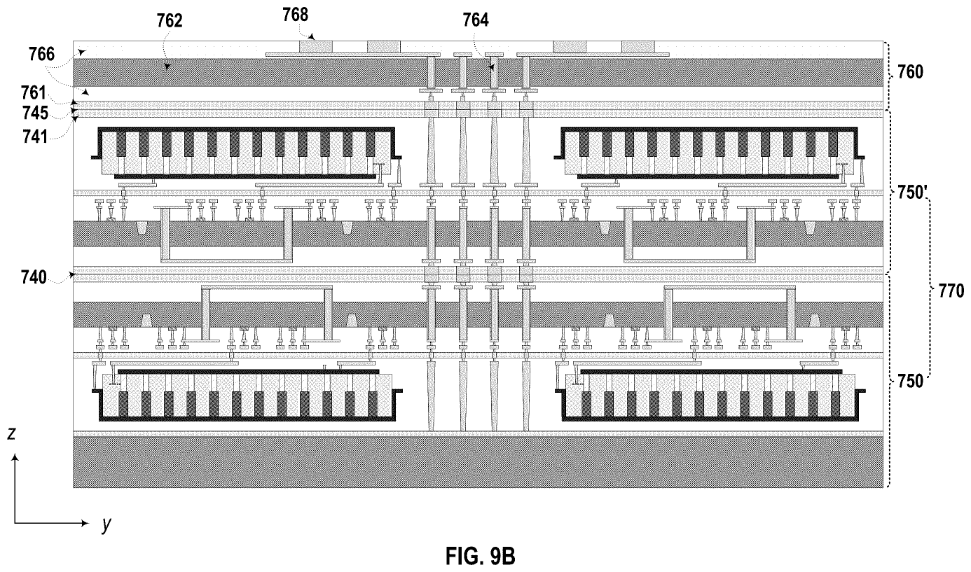

FIG. 8 illustrates a flowchart of a fabricating method 800 for forming a semiconductor structure, according to some implementations of the present disclosure. FIGS. 9A-9B illustrate schematic views of a semiconductor device at certain fabricating stages of the method 800 shown in FIG. 8, according to various implementations of the present disclosure. It is understood that the operations shown in method 800 are not exhaustive and that other operations can be performed as well before, after, or between any of the illustrated operations. Further, some of the operations may be performed simultaneously, or in a different order than shown in FIG. 8.

As shown in FIG. 8, method 600 can start at operation 802, in which two semiconductor stacks are bonded in a face-to-face manner. FIG. 9A illustrates a schematic side cross-sectional view of a semiconductor structure in the y-z plane after operation 802 of method 800.

As shown in FIG. 9A, two semiconductor stacks 750 and 750′ can be bonded in a face-to-face manner. In some implementations, each of the two semiconductor stacks 750 and 750′ can be formed by method 600 described above in connections with FIGS. 6 and 7A-7H. In some implementations, the bonding of two semiconductor stacks 750 and 750′ can include hybrid bonding. In some implementations, the pad contacts 738 and 738′ in the pad-out layers 735 and 735′ of the two semiconductor stacks 750 and 750′ can in contact with each other at bonding interface 740 after the bonding.

As illustrated in FIG. 9A, one semiconductor stack 750′ is flipped upside down. The pad-out layer 735′ facing down is bonded with the pad-out layer 735 facing up, i.e., in a face-to-face manner, thereby forming a bonding interface 740 shown in FIG. 9A. In some implementations, a treatment process, e.g., a plasma treatment, a wet treatment, and/or a thermal treatment, is applied to the bonding surfaces prior to the bonding. After the bonding, the pad contacts 738 and 738′ in the pad-out layers 735 and 735′ are aligned and in contact with one another, such that the through interconnects in the through interconnect region 799 can be electrically connected with each other across the bonding interface 740. As such, the bonded structure 770 is formed.

Referring back to FIG. 8, method 800 proceeds to operation 804, in which a pad-out interconnect layer can be bonded to the bonded structure. FIG. 9B illustrates a schematic side cross-sectional view of a semiconductor structure in the y-z plane after operation 804 of method 800.

As shown in FIG. 9B, the original substrate 711′ of the semiconductor stack 750′ can be removed, and a bonding layer 741 including bonding pads can be formed. The bonding layer 741 can include a plurality of bonding pads surrounded by dielectrics. A fabricating process of forming the bonding layer 741 can be referred to in the descriptions above and not repeated herein.

In some implementations, a pad-out interconnect layer 760 can be bonded to the bonding layer 741 at bonding interface 745. As shown in FIG. 9B, the pad-out interconnect layer 760 can include a substrate 762, a plurality of through substrate contacts 764, a plurality of the interconnect layers 766 coupled with both ends of the through substrate contacts 764, a plurality of pad contacts 768 coupled with the interconnect layers 766 on one side of the substrate 762, and a bonding layer 761 including bonding pads on the other side of the substrate 762. In some implementations, the bonding layer 761 of the pad-out interconnect layer 760 is bonded to the bonding layer 741 of the semiconductor stack 750′. In some implementations, the bonding of the bonding layers 741 and 761 can include hybrid bonding. In some implementations, the bonding contacts in the bonding layers 741 and 761 are aligned and in contact with one another after the bonding.

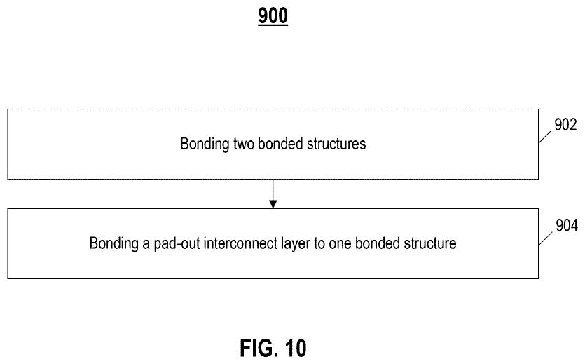

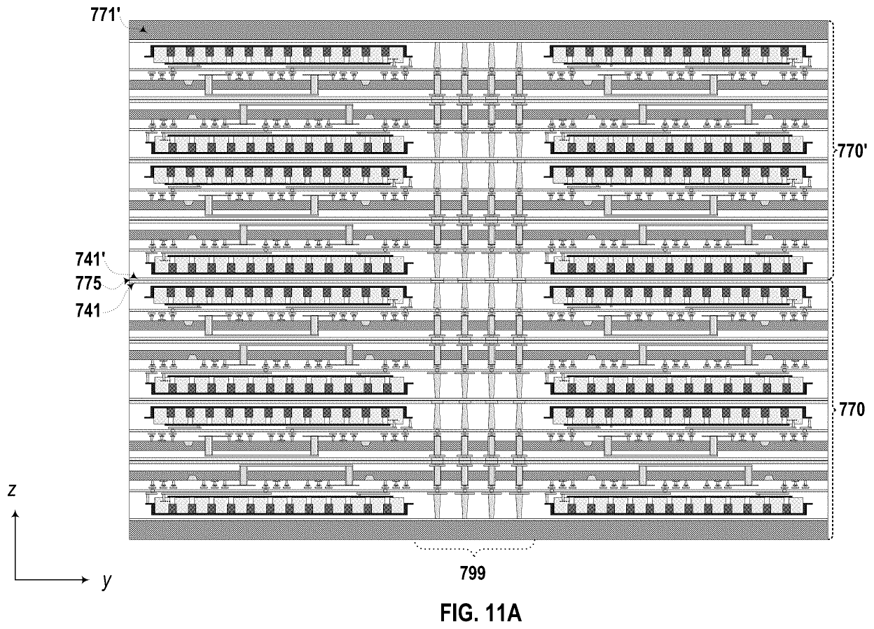

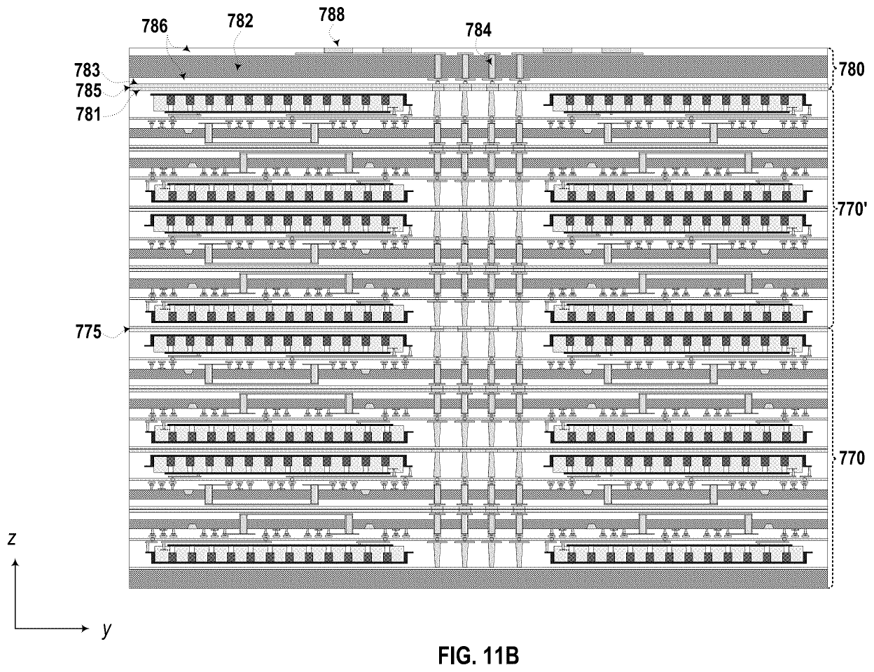

FIG. 10 illustrates a flowchart of a fabricating method 900 for forming a semiconductor structure, according to some implementations of the present disclosure. FIGS. 11A-11B illustrate schematic views of a semiconductor device at certain fabricating stages of the method 900 shown in FIG. 10, according to various implementations of the present disclosure. It is understood that the operations shown in method 900 are not exhaustive and that other operations can be performed as well before, after, or between any of the illustrated operations. Further, some of the operations may be performed simultaneously, or in a different order than shown in FIG. 10.

As shown in FIG. 10, method 900 can start at operation 902, in which two bonded structures are bonded in a face-to-face manner. FIG. 11A illustrates a schematic side cross-sectional view of a semiconductor structure in the y-z plane after operation 902 of method 900.

As shown in FIG. 11A, two bonded structures 770 and 770′ can be bonded in a face-to-face manner. In some implementations, each of the two bonded structures 770 and 770′ can be formed by method 800 described above in connections with FIGS. 8 and 9A-9B. In some implementations, the bonding of two bonded structures 770 and 770′ can include hybrid bonding. In some implementations, the bonding contacts in the bonding layers 741 and 741′ of the two bonded structures 770 and 770′ can be in contact with each other at bonding interface 775 after the bonding.

As illustrated in FIG. 11A, one bonded structure 770′ is flipped upside down. The bonding layer 741′ facing down is bonded with the bonding layer 741 facing up, i.e., in a face-to-face manner, thereby forming a bonding interface 775 shown in FIG. 11A. In some implementations, a treatment process, e.g., a plasma treatment, a wet treatment, and/or a thermal treatment, is applied to the bonding surfaces prior to the bonding. After the bonding, the bonding contacts in the bonding layers 741 and 741′ are aligned and in contact with one another, such that the through interconnects in the through interconnect region 799 can be electrically connected with each other across the bonding interface 775.

Referring back to FIG. 10, method 900 proceeds to operation 904, in which a pad-out interconnect layer can be bonded to one bonded structure. FIG. 11B illustrates a schematic side cross-sectional view of a semiconductor structure in the y-z plane after operation 904 of method 900.

As shown in FIG. 11B, the original substrate 771′ of the bonded structure 770′ can be removed, and a bonding layer 781 including bonding pads can be formed. The bonding layer 781 can include a plurality of bonding pads surrounded by dielectrics. A fabricating process of forming the bonding layer 781 can be referred to in the descriptions above and not repeated herein.

In some implementations, a pad-out interconnect layer 780 can be bonded to the bonding layer 781 at bonding interface 785. As shown in FIG. 11B, the pad-out interconnect layer 780 can include a substrate 782, a plurality of through substrate contacts 784, a plurality of the interconnect layers 786 coupled with both ends of the through substrate contacts 784, a plurality of pad contacts 788 coupled with the interconnect layers 786 on one side of the substrate 782, and a bonding layer 783 including bonding pads on the other side of the substrate 782. In some implementations, the bonding layer 783 of the pad-out interconnect layer 780 is bonded to the bonding layer 781 of the bonded structure 770′. In some implementations, the bonding of the bonding layers 783 and 781 can include hybrid bonding. In some implementations, the bonding contacts in the bonding layers 783 and 781 are aligned and in contact with one another after the bonding.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations but should be defined only in accordance with the following claims and their equivalents.

What is claimed is:

1. A semiconductor structure, comprising:
a first semiconductor stack, comprising:
a first memory array layer comprising first arrays of memory cells,
a first peripheral circuit layer on the first memory array layer, and comprising first transistors formed on a first semiconductor layer,
a first bonding layer on the first semiconductor layer, and
a first interconnect structure vertically extending through the first semiconductor stack, located between adjacent first arrays of memory cells, and extending through the first semiconductor layer and the first bonding layer; and
a second semiconductor stack, comprising:
a second memory array layer comprising arrays of memory cells,
a second peripheral circuit layer on the second memory array layer, and comprising second transistors formed on a second semiconductor layer,
a second bonding layer on the second semiconductor layer, and
a second interconnect structure vertically extending through the second semiconductor stack, located between adjacent arrays of memory cells, and extending through the first semiconductor layer and the second bonding layer,
wherein the first bonding layer is bonded with the second bonding layer, the first interconnect structure is in contact with the second interconnect structure, the first semiconductor layer is located between the first bonding layer and the first peripheral circuit layer, and the second semiconductor layer is located between the second bonding layer and the second peripheral circuit layer.

2. The semiconductor structure of claim 1, wherein each of first arrays and second arrays of memory cells comprises:
a transistor layer comprising an array of vertical transistors, each vertical transistor comprising a channel structure extending vertically; and
a storage layer vertically stacked on the transistor layer and comprising an array of capacitors each coupled with a corresponding one of the array of vertical transistors.

3. The semiconductor structure of claim 1, wherein:
the first semiconductor stack and the second semiconductor stack are hybrid bonded with each other; and
a first conductive pad of the first interconnect structure is in contact with a second conductive pad of the second interconnect structure.

4. The semiconductor structure of claim 3, wherein: the first bonding layer comprises a first carbon nitride layer where the first conductive pad is embedded; and
the second bonding layer comprises a second carbon nitride layer where the second conductive pad is embedded.

5. The semiconductor structure of claim 3, wherein: the first bonding layer comprises a first silicon oxide layer where the first conductive pad is embedded; and
the second bonding layer comprises a second silicon oxide layer where the second conductive pad is embedded.

6. The semiconductor structure of claim 1, wherein: a thickness of the first semiconductor stack or the second semiconductor stack is less than 12 μm.

7. The semiconductor structure of claim 1, wherein: the first memory array layer is bonded with the first peripheral circuit layer; and
the second memory array layer is bonded with the second peripheral circuit layer.

8. The semiconductor structure of claim 1, wherein: the first semiconductor stack further comprises a first bridge contact structure laterally extending between the first semiconductor layer and the second semiconductor layer, and vertically extending through the first semiconductor layer twice to interconnect two of the first transistors; and
the second semiconductor stack further comprises a second bridge contact structure laterally extending between the first semiconductor layer and the second semiconductor layer, and vertically extending through the second semiconductor layer twice to interconnect two of the second transistors.

9. The semiconductor structure of claim 2, wherein the array of capacitors comprises:
a plurality of first electrodes coupled with the array of vertical transistors; and
a plurality of second electrodes coupled with a common conductive layer.

10. The semiconductor structure of claim 9, wherein the common conductive layer comprises:
a main lateral plate in contact with the plurality of second electrodes;
a vertical plate in contact with an edge of the main lateral plate; and
a lateral landing portion in contact with the vertical plate, and in contact with a capacitor interconnection structure, which is coupled with the first transistors or second transistors.

11. A semiconductor structure, comprising:
a first semiconductor stack, comprising:
a first memory array layer comprising:
first arrays of memory cells, and
a first through array interconnect structure located between the first arrays of memory cells;
a first peripheral circuit layer bonded with the first memory array layer, the first peripheral circuit layer comprising:
first transistors formed on a first semiconductor layer, and
a first through circuit interconnect structure extending through the first semiconductor layer and in contact with the first through array interconnect structure; and
a second semiconductor stack, comprising:
a second memory array layer comprising:
second arrays of memory cells, and
a second through array interconnect structure located between the second arrays of memory cells;
a second peripheral circuit layer bonded with the second memory array layer, the second peripheral circuit layer comprising:
second transistors formed on a second semiconductor layer, and
a second through circuit interconnect structure extending through the second semiconductor layer and in contact with the second through array interconnect structure,
wherein the first semiconductor stack is bonded with the second semiconductor stack, such that the first through circuit interconnect structure is in contact with the second through circuit interconnect structure.

12. A method of forming a semiconductor structure, comprising:
forming a first wafer, comprising:
forming a first memory array layer comprising first arrays of memory cells,
forming a first peripheral circuit layer on the first memory array layer, and comprising first transistors formed on a first semiconductor layer, and
forming a first interconnect structure vertically extending through the first wafer, located between adjacent first arrays of memory cells, and extending through the first semiconductor layer; and
forming a second wafer, comprising:
forming a second memory array layer comprising arrays of memory cells,
forming a second peripheral circuit layer on the second memory array layer, and comprising second transistors formed on a second semiconductor layer, and
forming a second interconnect structure vertically extending through the second wafer, located between adjacent arrays of memory cells, and extending through the first semiconductor layer; and
bonding the first wafer and the second wafer to form a bonded structure, such that the first interconnect structure is in contact with the second interconnect structure, and the first semiconductor layer is facing the second semiconductor layer.

13. The method of claim 12, further comprising:
after bonding, cutting the bonded structure into a plurality of semiconductor structures.

14. The method of claim 12, wherein forming the first memory array layer or the second memory array layer comprises:
forming a transistor layer comprising an array of vertical transistors, each vertical transistor comprising a channel structure extending vertically; and
forming a storage layer vertically stacked on the transistor layer and comprising an array of capacitors each coupled with a corresponding one of the array of vertical transistors.

15. The method of claim 12, wherein bonding the first wafer and the second semiconductor further comprises: bonding a first bonding layer including a dielectric layer and a first conductive pad to a second bonding layer including carbon nitride and a second conductive pad.

16. The method of claim 12, wherein forming the first wafer or the second wafer further comprises:
thinning the first semiconductor layer or the second semiconductor layer, such that a thickness of the first wafer or the second wafer is less than 12 μm.

17. The method of claim 12, wherein: forming the first wafer further comprises bonding the first memory array layer and the first peripheral circuit layer; and
forming the second wafer further comprises bonding the second memory array layer and the second peripheral circuit layer.

18. The method of claim 12, wherein: forming the first wafer further comprises forming a first bridge contact structure laterally extending between the first semiconductor layer and the second semiconductor layer, and vertically extending through the first semiconductor layer twice to interconnect two of the first transistors; and
forming the second wafer further comprises forming a second bridge contact structure laterally extending between the first semiconductor layer and the second semiconductor layer, and vertically extending through the second semiconductor layer twice to interconnect two of the second transistors.

19. The method of claim 14, wherein forming the storage layer comprises:
forming a plurality of first electrodes coupled with the array of vertical transistors;
forming a plurality of second electrodes isolated with the plurality of first electrodes by a dielectric layer, and
forming a common conductive layer coupled with the plurality of second electrodes.

20. The method of claim 19, wherein forming the common conductive layer comprises:
forming a main lateral plate in contact with the plurality of second electrodes;
forming a vertical plate in contact with an edge of the main lateral plate; and
forming a lateral landing portion in contact with the vertical plate, and in contact with a capacitor interconnection structure.
